(19) United States
(12) Patent Application Publication
(10) Pub. No.: US 2016/0020375 A1
(43) Pub. Date: Jan. 21, 2016

(54) THERMOELECTRIC POWER GENERATION DEVICE AND THERMOELECTRIC POWER GENERATION METHOD USING THE SAME

(71) Applicants: JFE STEEL CORPORATION, Chiyoda-ku, Tokyo (JP); KELK LTD., Hiratsuka-shi, Kanagawa (JP)

(72) Inventors: Takashi KUROKI, Tokyo (JP); Kazuhisa KABEYA, Tokyo (JP); Akio FUJIBAYASHI, Tokyo (JP); Hiromasa KAIBE, Kawasaki-shi (JP); Takeshi KAJIHARA, Hiratsuka-shi (JP); Kazuya MAKINO, Hiratsuka-shi (JP); Hirokuni HACHIUMA, Hiratsuka-shi (JP)

(73) Assignees: JFE STEEL CORPORATION, Tokyo (JP); KELK LTD., Hiratsuka-shi, Kanagawa (JP)

(21) Appl. No.: 14/772,848

(22) PCT Filed: Mar. 27, 2014
(86) PCT No.: PCT/JP2014/001806

§ 371 Date: Sep. 4, 2015

(30) Foreign Application Priority Data
Mar. 27, 2013 (JP) 2013-067145

(51) Int. Cl. H01L 35/32; H01L 35/30

(52) U.S. Cl. CPC H01L 35/32; H01L 35/30

(57) ABSTRACT

A thermoelectric power generation device includes: a thermoelectric power generation unit; and a transporter capable of moving the thermoelectric power generation unit. A thermoelectric power generation device including a thermoelectric power generation unit that converts heat energy which varies in release state into electric energy to recover the energy can thus be provided in a steel material manufacturing line in which a heat source flows.

### TECHNICAL FIELD

The disclosure relates to a thermoelectric power generation device that converts heat energy radiated from a steel material into electric energy to recover the energy, and a thermoelectric power generation method using the same.

### BACKGROUND

The Seebeck effect has long been known as a phenomenon in which a temperature difference between different types of conductors or semiconductors generates an electromotive force between the high temperature portion and the low temperature portion. The use of thermoelectric power generation elements based on such a property to directly convert heat into electric power has been known, too.

In recent years, for example, manufacturing facilities such as steel plants have been increasing their efforts to use energy previously disposed of as waste heat, e.g. heat energy radiated from a steel material, by power generation using the above-mentioned thermoelectric power generation elements.

As a method for using heat energy, for example, JP S59-198883 A (Patent Literature (PTL) 1) describes a method of placing a heat receiving device to face a high temperature object, and converting the heat energy of the high temperature object into electric energy to recover the energy.

JP S60-34084 A (PTL 2) describes a method of bringing a thermoelectric element module into contact with heat energy processed as waste heat, and converting the heat energy into electric energy to recover the energy.

### CITATION LIST

### Patent Literature

PTL 1: JP S59-198883 A

PTL 2: JP S60-34084 A

PTL 1 describes its applicability to a slab continuous casting line, but fails to take into consideration the variations of the heat source during operation, such as the temperature distribution of the slab in actual operation and the variations of the quantity of released heat (heat energy) due to the variations of the slab amount.

PTL 2 has a problem in that, while the module needs to be fixed to the heat source, the module cannot be installed for a moving heat source.

Moreover, in conventional thermoelectric power generation methods, a thermoelectric power generation device can only be installed far from a steel material, in order to prevent the device from breakage caused by, for example, a change in height of the steel material in a non-steady state in which the front end, the back end, or the like of the steel material serves as a heat source. This raises the following problem: when the thermoelectric power generation device is installed far from the steel material, the heat energy of the high temperature object cannot be adequately transferred to the thermoelectric power generation device, which hinders efficient conversion into electric energy.

It could therefore be helpful to provide a thermoelectric power generation device including a thermoelectric power generation unit capable of stably converting generated heat energy into electric energy to recover the energy even in the case where the generation state of the heat source in operation varies in any of various manufacturing processes and particularly in a continuous casting line, a slab continuous casting line, etc. where the heat source flows, and a thermoelectric power generation method using the same.

### SUMMARY

As a result of conducting intensive studies to solve the problems stated above, we discovered that high-efficiency thermoelectric power generation can be realized by effectively adjusting, for example, the distance between the heat source and the thermoelectric power generation unit depending on the heat energy release state, and developed a thermoelectric power generation device that enables efficient heat utilization especially in a steel material manufacturing line, together with a thermoelectric power generation method using the same.

The disclosure is based on the aforementioned discoveries.

We thus provide the following.

1. A thermoelectric power generation device including: a thermoelectric power generation unit that converts heat energy radiated from a steel material into electric energy; and a transporter capable of moving the thermoelectric power generation unit.

2. The thermoelectric power generation device according to the foregoing 1, wherein the thermoelectric power generation unit is installed to face the steel material and depending on an output of the thermoelectric power generation unit.

3. The thermoelectric power generation device according to the foregoing 1 or 2, wherein the thermoelectric power generation unit is installed nearer the steel material in a low temperature portion with low output than in a high temperature portion with high output, depending on an output of the thermoelectric power generation unit.

4. The thermoelectric power generation device according to any of the foregoing 1 to 3, wherein one or more thermoelectric power generation modules or thermoelectric elements in the thermoelectric power generation unit are arranged more densely in a high temperature portion with high output than in a low temperature portion with low output, depending on an output of the thermoelectric power generation unit.

5. The thermoelectric power generation device according to any of the foregoing 1 to 4, including a heat reflector.

6. The thermoelectric power generation device according to any of the foregoing 1 to 5, wherein the thermoelectric power generation unit is installed further depending on at least one of a temperature of the thermoelectric power generation unit and a temperature of the steel material.

7. The thermoelectric power generation device according to any of the foregoing 1 to 6, wherein the transporter controls a distance between the thermoelectric power generation unit and the steel material, depending on at least one of a temperature and an output obtained by measuring at least one of: a temperature of the steel material; a temperature of the thermoelectric power generation unit; and an output of the thermoelectric power generation unit.

8. The thermoelectric power generation device according to any of the foregoing 1 to 7, wherein the thermoelectric power generation device is shaped to surround an outer periphery of the steel material.

9. The thermoelectric power generation device according to any of the foregoing 1 to 8, wherein the thermoelectric power generation device is provided with at least one opening.

10. A thermoelectric power generation method of receiving heat of a steel material and performing thermoelectric power generation, using the thermoelectric power generation device according to any of the foregoing 1 to 9.

11. The thermoelectric power generation device according to the foregoing 1, wherein the thermoelectric power generation unit includes a mechanism for monitoring a temperature of the thermoelectric power generation unit, and the thermoelectric power generation device includes a position adjusting mechanism for, when the temperature monitored by the mechanism reaches an upper limit of a tolerable temperature range of the thermoelectric power generation unit, moving the thermoelectric power generation unit to keep the temperature of the thermoelectric power generation unit at or below the upper limit of the tolerable temperature range.

12. The thermoelectric power generation device according to the foregoing 11, wherein the mechanism for monitoring has a thermocouple that is placed at a position for measuring a temperature of a heat receiving sheet of the thermoelectric power generation unit.

13. The thermoelectric power generation device according to the foregoing 11, wherein the thermoelectric power generation unit is installed to face the steel material and depending on at least one of a temperature and an output of the thermoelectric power generation unit.

14. A thermoelectric power generation method of receiving heat of a steel material to generate power using the thermoelectric power generation device according to any of the foregoing 11 to 13, and moving the thermoelectric power generation unit of the thermoelectric power generation device using generated electric energy.

The thermoelectric power generation unit and the heat source can be kept at, for example, a distance contributing to high power generation efficiency, thus improving the power generation efficiency. Hence, heat energy generated from a manufacturing line can be recovered at a high level as compared with the conventional techniques.

### BRIEF DESCRIPTION OF THE DRAWINGS

In the accompanying drawings:

FIG. 1 is a schematic diagram for describing an embodiment;

FIG. 2 is a sectional diagram of a thermoelectric power generation unit according to an embodiment;

FIG. 3 is another schematic diagram for describing an embodiment;

FIG. 4 is an explanatory diagram of a thermoelectric power generation device representing an embodiment;

FIG. 5 is an explanatory diagram of another thermoelectric power generation device representing an embodiment;

FIG. 6 is a diagram illustrating an example of installation of a thermoelectric power generation device according to an embodiment;

FIG. 7 is a diagram illustrating another installation position of a thermoelectric power generation device according to an embodiment;

FIG. 8 is a diagram illustrating another installation position of a thermoelectric power generation device according to an embodiment;

FIG. 9 is a graph illustrating the relationship between the distance between a steel material and a thermoelectric power generation unit and the power output ratio;

FIG. 10 is a diagram illustrating an example of installation of thermoelectric power generation units;

FIG. 11 is a sectional diagram illustrating an example of arrangement of thermoelectric power generation modules in each thermoelectric power generation unit;

FIG. 12 is a graph illustrating the relationship between the distance between a pipe or tube material and a thermoelectric power generation unit and the power output ratio;

FIGS. 13(a) and (b) are each a diagram illustrating an example of installation of a thermoelectric power generation device having a reflector;

FIGS. 14(a) and (b) are each a diagram illustrating another example of installation of a thermoelectric power generation device having a reflector;

FIG. 15(A) to (D) are each a diagram illustrating another example of installation of thermoelectric power generation units; and

FIG. 16 is a diagram illustrating an example of attaching a temperature monitoring mechanism to a thermoelectric power generation unit.

### DETAILED DESCRIPTION

The following describes the disclosed technique in detail.

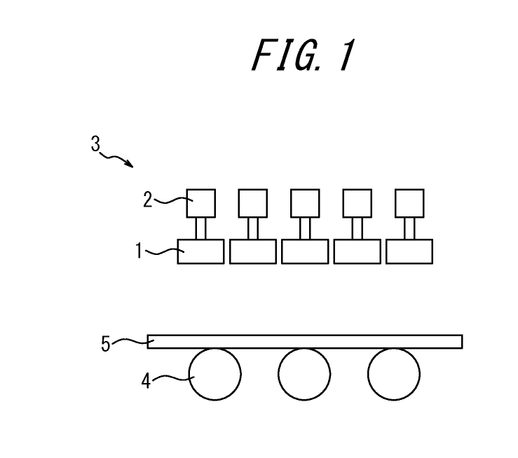

FIG. 1 is a schematic diagram for describing an embodiment of the disclosed thermoelectric power generation device. In FIG. 1, reference sign 1 is a thermoelectric power generation unit, 2 is a transporter, 3 is a thermoelectric power generation device, 4 is a table roller, and 5 is a steel material.

The thermoelectric power generation device 3 includes: the thermoelectric power generation unit 1 installed to face the steel material 5 as a heat source; and the transporter 2 of the thermoelectric power generation unit. The steel material 5 is typically on the upper surface of the table roller.

The steel material is not particularly limited as long as it is a ferrous metal heated in a steelworks, a processing plant, or the like to a temperature of about 600° C. to 1300° C. Preferable examples include a hot slab in a continuous caster, a slab, a rough bar, and a hot-rolled steel strip in a hot rolling device, a sheet material and a pipe or tube material in a forge welded pipe or tube facility, and other bar steels such as a steel pipe or tube, a steel bar, a wire rod, and a rail (hereafter simply referred to as “steel material”).

The thermoelectric power generation device includes at least one thermoelectric power generation unit in the width direction and length direction of the steel material. The thermoelectric power generation unit includes: a heat receiver facing the steel material; at least one thermoelectric power generation module; and a heat releaser.

The heat receiver reaches several degrees to several tens of degrees higher than the high temperature side of the thermoelectric element and, in some cases, reaches about several hundreds of degrees higher than the high temperature side of the thermoelectric element, depending on the material. The heat receiver is accordingly made of any material having heat resistance and durability at the temperature. For example, copper, a copper alloy, aluminum, an aluminum alloy, ceramics, carbon, and other typical iron and steel materials may be used as the heat receiver.

The heat releaser may be conventionally known means. Though the heat releaser is not particularly limited, preferable examples include: a cooling device equipped with a fin; a water-cooling device utilizing contact heat transfer; a heat sink utilizing boiling heat transfer; and a water-cooling sheet having a refrigerant passage.

Moreover, water-cooling the low temperature side of the thermoelectric power generation unit by spray cooling or the like can efficiently cool the low temperature side. Particularly in the case where the thermoelectric power generation unit is installed below the heat source, spray cooling with an appropriately positioned spray enables the low temperature side of the thermoelectric power generation unit to be efficiently cooled without cooling the high temperature side of the thermoelectric power generation unit, by dropping residual water below the table. In the case of performing spray cooling, the side touched and cooled by the sprayed refrigerant is the heat releaser.

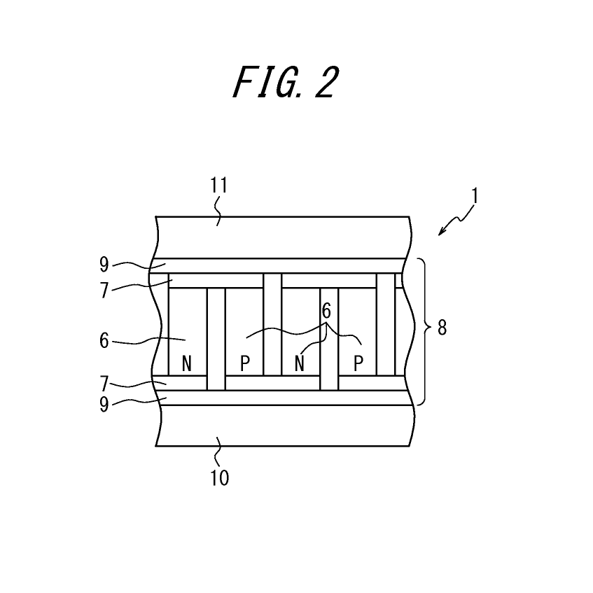

A thermoelectric power generation module 8 includes: a two-dimensionally arranged thermoelectric element group in which p-type and n-type semiconductors as thermoelectric elements 6 are connected by several tens to several thousands of pairs of electrodes 7; and an insulator 9 placed on both sides of the thermoelectric element group, as illustrated in FIG. 2. The thermoelectric power generation module 8 may also have a heat conductive sheet or a protection sheet on one or both sides. The respective protection sheets may also serve as a heat receiver 10 and a heat releaser 11.

In the case where the cooling sheet which is the heat receiver 10 and/or the heat releaser 11 is an insulator or is coated with an insulator on its surface, the cooling sheet may substitute for the insulator 9. In the drawing, reference sign 1 is a thermoelectric power generation unit, 6 is a thermoelectric element, 7 is an electrode, 9 is an insulator, 8 is a thermoelectric power generation module, 10 is a heat receiver, and 11 is a heat releaser.

The above-mentioned heat conductive sheet may be provided, for example, between the heat receiver and the thermoelectric power generation module, between the heat releaser and the thermoelectric power generation module, and between the insulator and the protection sheet, in order to reduce the heat contact resistance between the members and further improve the thermoelectric power generation efficiency. The heat conductive sheet has predetermined heat conductivity. The heat conductive sheet is not particularly limited as long as it can be used in the use environments of the thermoelectric power generation module. Examples of the heat conductive sheet include a graphite sheet.

The size of the thermoelectric power generation module is preferably not greater than 1×10⁻² m². When the size of the module is approximately in this range, the thermoelectric power generation module can be kept from deformation. The size of the thermoelectric power generation module is more preferably not greater than 2.5×10⁻³ m².

The size of the thermoelectric power generation unit is preferably not greater than 1 m². When the size of the thermoelectric power generation unit is not greater than 1 m², the deformation between the thermoelectric power generation modules and the deformation of the thermoelectric power generation unit itself can be suppressed. The size of the thermoelectric power generation unit is more preferably not greater than 2.5×10⁻¹ m².

The thermoelectric power generation device includes the transporter capable of moving the thermoelectric power generation unit, and can control the distance between the thermoelectric power generation unit and the steel material by the transporter. The distance is preferably controlled using a power cylinder.

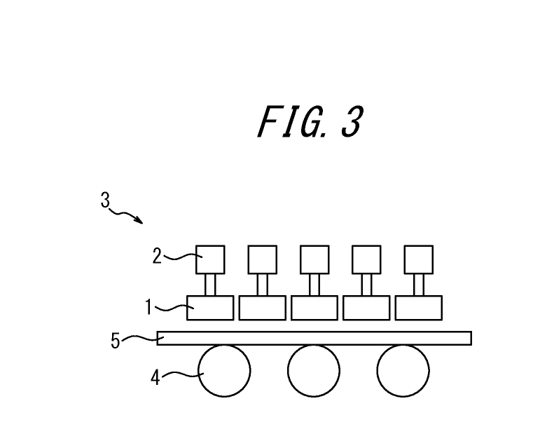

The transporter is capable of moving the thermoelectric power generation unit up and down, as illustrated in FIGS. 1 and 3. The transporter capable of moving the thermoelectric power generation unit back and forth and/or right and left can also be used without any particular problem.

In a situation where the temperature varies little, the means for controlling the distance may be, for example, the following manual transporter: the thermoelectric power generation unit is fixed by a bolt or a slide-type bolt, and the bolt is loosened to move the thermoelectric power generation unit and then tightened again.

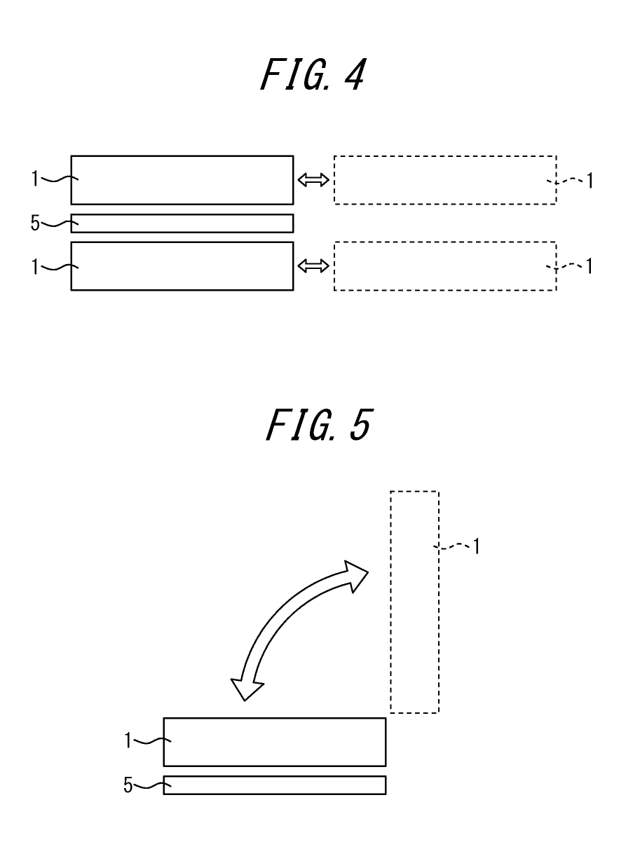

The transporter may be a transporter for conducting sliding movement as illustrated in FIG. 4 or open/close movement as illustrated in FIG. 5.

In the case of performing spray cooling as mentioned earlier, a spray cooling device may or may not be moved together with the thermoelectric power generation unit and the like.

The thermoelectric power generation device can include, in addition to the transporter, the thermoelectric power generation unit that is installed to face the steel material and depending on the output of the thermoelectric power generation unit.

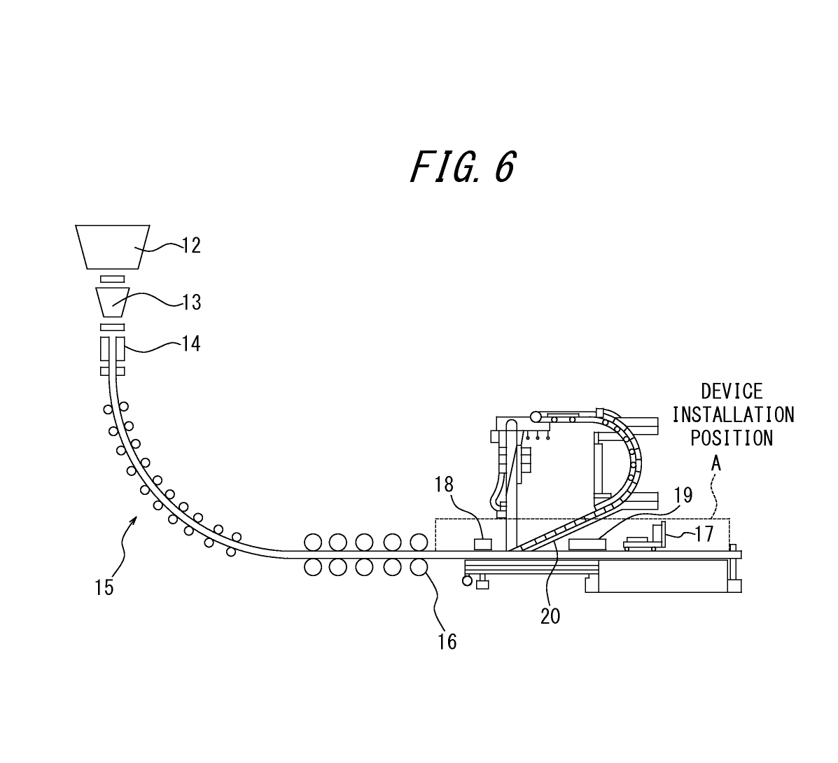

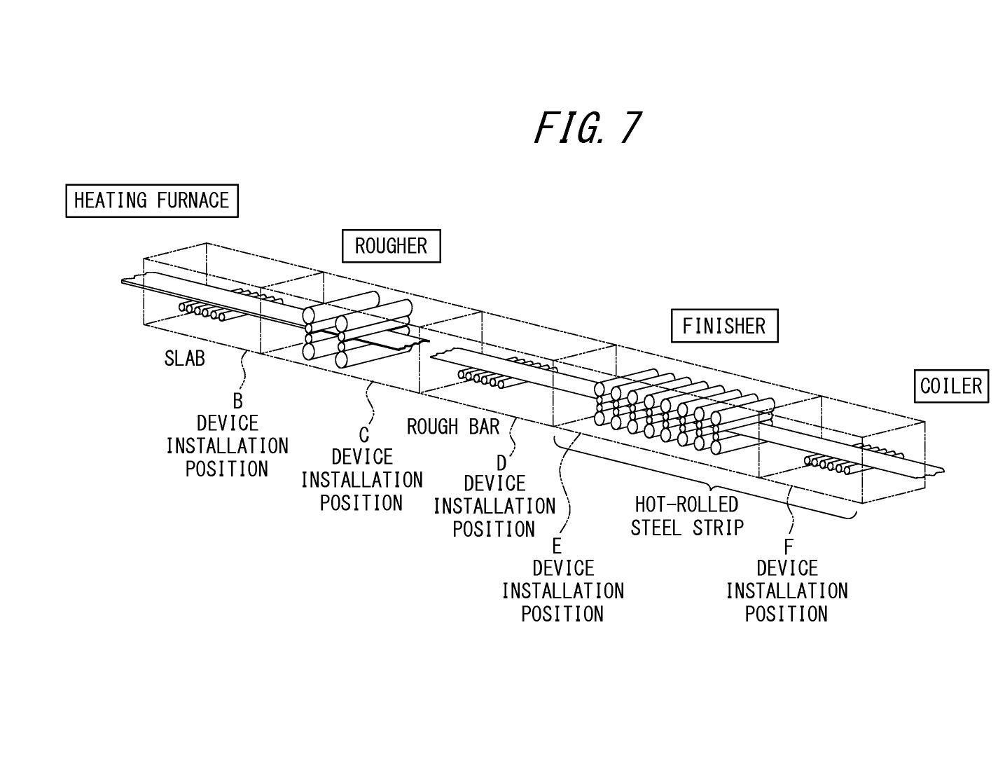

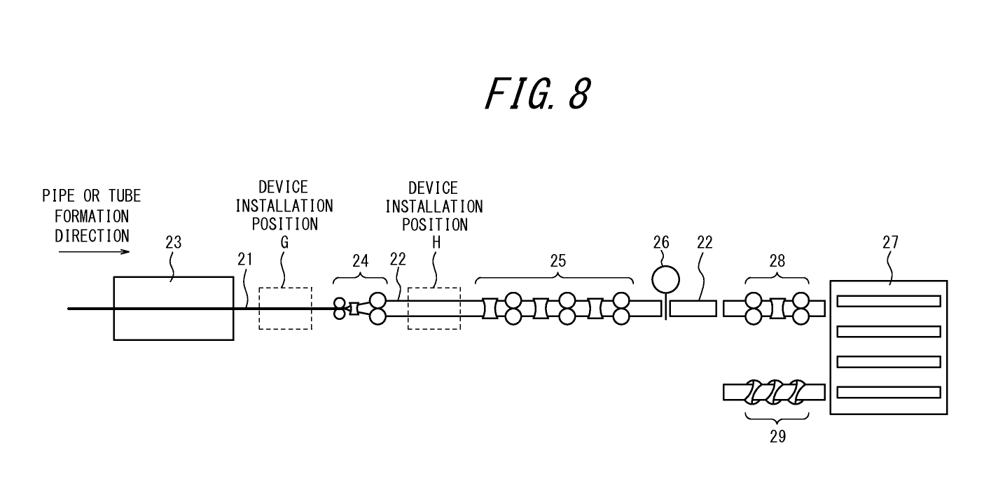

By installing, depending on the temperature of the steel material, such a thermoelectric power generation unit in: any position (A in FIG. 6) of upstream of a slab cutting device 17 in a continuous casting device, inside the slab cutting device, the underside of the slab cutting device, and the exit side of the slab cutting device as illustrated in FIG. 6; any position (B to F in FIG. 7) from upstream of a rougher through a finisher to a hot-rolled steel strip conveyance path as illustrated in FIG. 7; and any position of a steel sheet conveyance path (G in FIG. 8) from a heating furnace to a forming machine/forge welder and a pipe or tube material conveyance path (H in FIG. 8) in a forge welded pipe or tube line as illustrated in FIG. 8, efficient power generation can be performed in response to, for example, the temperature variations of the heat source in actual operation. In FIG. 6, reference sign 12 is a ladle, 13 is a tundish, 14 is a mold, 15 is a slab cooling device, 16 is a roller group such as straightening rolls, 17 is a slab cutting device, 18 is a thermometer, 19 is a thermoelectric power generation device, and 20 is a dummy bar table. In FIG. 8, reference sign 21 is a steel sheet, 22 is a pipe or tube material, 23 is a heating furnace, 24 is a forming machine/forge welder, 25 is a hot reducer, 26 is a rotary hot saw, 27 is a cooling bed, 28 is a sizer, and 29 is a straightener.

Moreover, attaching the thermoelectric power generation unit to the underside of the dummy bar table 20 for recovering a slab for adjustment is preferable in terms of avoiding an increase of the number of components in the facility.

Since the temperature of the steel material is the same to a certain extent according to the size or type, the installation position of the thermoelectric power generation unit may be set beforehand depending on the size or type. The installation position of the thermoelectric power generation unit may be set beforehand depending on the size or type, from the output power track records for each thermoelectric power generation unit and/or the output power prediction values based on the temperature and the like. In addition, the distance between the thermoelectric power generation unit and the steel material as the heat source and the arrangement of the thermoelectric power generation modules in the thermoelectric power generation unit may be determined upon facility introduction.

The thermoelectric power generation device (thermoelectric power generation unit) may be installed not only above the steel material but below or on the side of the steel material. The thermoelectric power generation device (thermoelectric power generation unit) may be installed not only in one position but in a plurality of positions.

The thermometer 18 may be installed on the upstream side of the thermoelectric power generation device 19 as illustrated in FIG. 6, so that the distance between the thermoelectric power generation unit and the steel material can be controlled depending on the measurement of the thermometer. For example, even in the case where the temperature of the steel material varies due to a production lot change or the like, such a function enables thermoelectric power generation to be performed appropriately in response to the temperature variation or the like, thus further improving the thermoelectric power generation efficiency.

The thermometer is preferably a contactless thermometer such as a radiation thermometer. In the case where the line stops intermittently, however, a thermocouple may be brought into contact for measurement each time the line stops. As the measurement frequency, it is desirable to install the thermometer in the line and automatically measure the temperature on a regular basis, though an operator may manually measure the temperature in the case where the manufacturing conditions are changed.

If the relationship between the temperature of the steel material and the distance corresponding to the most efficient thermoelectric power generation is determined beforehand, for example, the distance between the thermoelectric power generation unit 1 and the steel material 5 illustrated in FIG. 3 can be appropriately controlled in response to temperature variations depending on the measurement of the thermometer.

The distance between the thermoelectric power generation unit and the steel material may be controlled depending on the output of the thermoelectric power generation unit. In detail, the distance between the thermoelectric power generation unit and the steel material as the heat source is adjusted to increase the power output. An actually measured output or an output value predicted from, for example, the temperature of the steel material may be used when adjusting the distance.

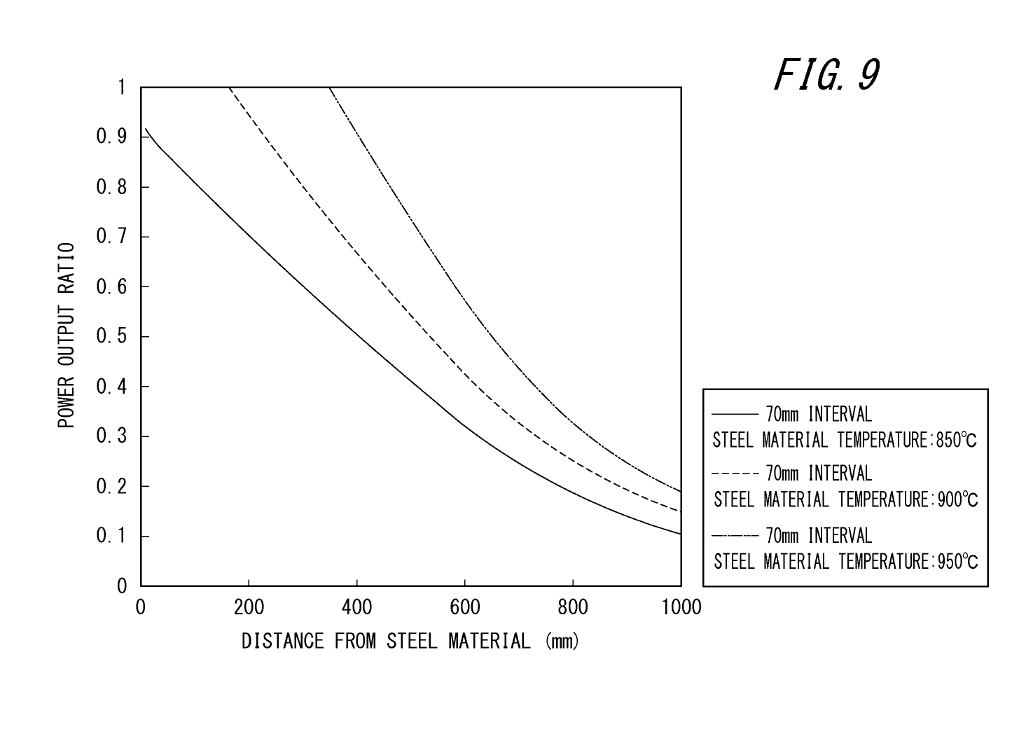

As an example of measuring the output of the thermoelectric power generation unit, FIG. 9 illustrates the relationship between the distance from the steel material to the thermoelectric power generation unit and the power output ratio where the power output ratio at the rated output is 1, as a result of conducting study with the thermoelectric power generation module interval in the thermoelectric power generation unit and the temperature of the steel material as parameters. As can be seen from the drawing, when using the thermoelectric power generation device including the thermoelectric power generation unit in which 50 mm square thermoelectric power generation modules are arranged at intervals of 70 mm, efficient thermoelectric power generation with a power output ratio of 1 can be realized by setting the distance between the thermoelectric power generation unit and the steel material or the like to 340 mm in the case where the temperature of the steel material is 950° C. and to 160 mm in the case where the temperature of the steel material is 900° C. In other words, it is preferable to determine the relationship as illustrated in FIG. 9 and set the distance so that the power output ratio in the drawing is 1 (rated output).

The output of the thermoelectric power generation unit is preferably set to the rated output as mentioned above. Here, the setting needs to be performed in consideration of the upper limit of the heat resistance temperature of the thermoelectric power generation unit so as not to break the thermoelectric element. In the case of taking the upper limit of the heat resistance temperature into consideration, the target power output ratio may be decreased optionally. The decrease of the target power output ratio is preferably up to about 0.7.

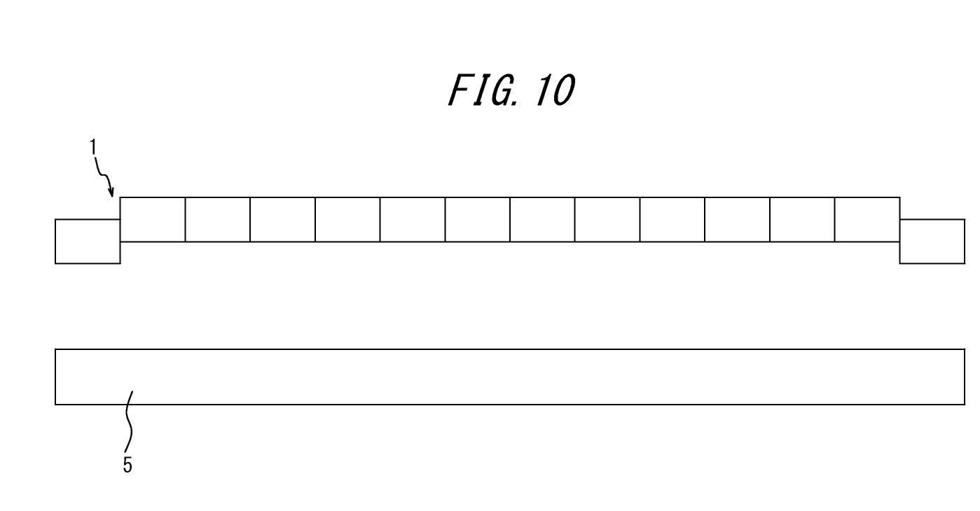

As illustrated in FIG. 10, the thermoelectric power generation unit may be installed nearer the steel material in the low temperature portion with low output than in the high temperature portion with high output, depending on at least one selected from the temperature of the steel material (hereafter including the temperature at the position at which faces the thermoelectric power generation unit, the temperature at the position suitable for temperature measurement, and the temperature in the vicinity thereof), temperature distribution of the steel material, and distance between the steel material and thermoelectric power generation unit corresponding to the configuration factor of the steel material and the temperature and output of the thermoelectric power generation unit. Such installation is particularly suitable for a continuous line where the temperature changes little. Since it is possible to measure the temperature distribution of the steel material in the width direction (the direction perpendicular to the travel direction of the steel material) beforehand and reflect the measurement in the above-mentioned distance, the power generation efficiency of the thermoelectric power generation unit can be further improved as compared with the case where the thermoelectric power generation unit is simply installed flat.

For example, efficient thermoelectric power generation can be performed by setting the distance between the thermoelectric power generation unit and the steel material to 340 mm in the center portion of the steel material and to 160 mm in the end portion of the steel material in FIG. 10.

The temperature distribution of the steel material in the width direction tends to sharply decrease at the position (hereafter referred to as “width end portion”) corresponding to about the sheet thickness or twice the sheet thickness from each width end of the steel material, as compared with the center portion of the steel material. It is therefore preferable to perform control such as moving the thermoelectric power generation unit to be nearer the steel material particularly in the width end portion. This is due to the possibility that the electric power obtained in the width end portion may be less than the electric power for moving the unit.

The width end portion of the steel material is typically low in temperature as mentioned above. In the embodiment in which the thermoelectric power generation unit is installed depending on the output of the thermoelectric power generation unit and the like, the shape in the case of installing the thermoelectric power generation unit may be, for example, half ellipse form. This provides the advantageous effect of enclosing the heat source, and has the feature of excellent heat insulation effect as the behavior of the heat flow changes. The thermoelectric power generation device thus exhibits excellent heat energy recovery effect.

The transporter for controlling the distance between the thermoelectric power generation unit and the steel material is included in this embodiment. Accordingly, for example even in the case where the temperature of the heat source varies in actual operation, the thermoelectric power generation device can generate power more efficiently by appropriately controlling the distance between the thermoelectric power generation unit and the steel material.

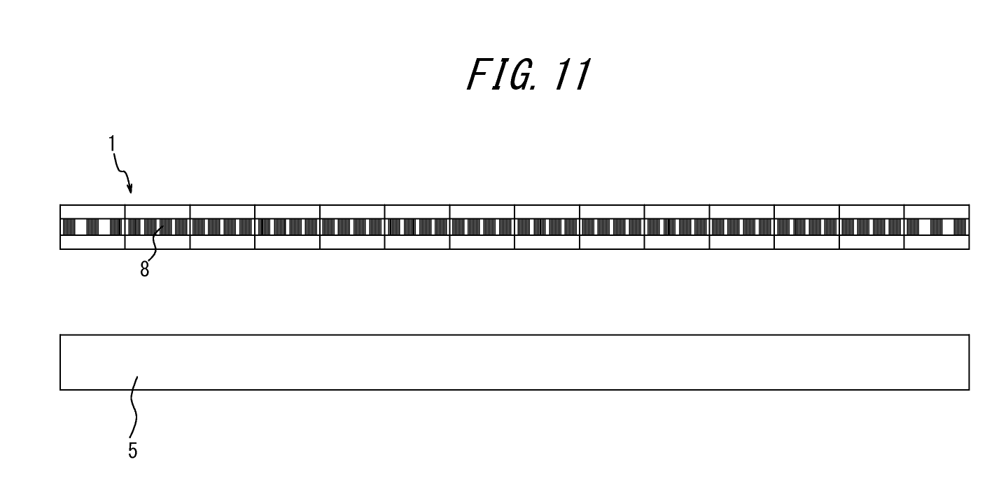

In the thermoelectric power generation device, the arrangement density of the thermoelectric power generation modules or thermoelectric elements in the thermoelectric power generation unit may be higher in the high temperature portion with high output than in the low temperature portion with low output, depending on at least one selected from the temperature, temperature distribution, and configuration factor of the steel material and the temperature and output of the thermoelectric power generation unit, as illustrated in FIG. 11. Such arrangement is also suitable for a continuous line where the temperature changes little. Since it is possible to measure the temperature distribution of the steel material in the width direction (the direction perpendicular to the travel direction of the steel material) beforehand and reflect the measurement in the above-mentioned arrangement density, the power generation efficiency of the thermoelectric power generation unit can be further improved as compared with the case where the thermoelectric power generation modules or the thermoelectric elements are simply arranged at fixed intervals.

The thermoelectric power generation modules or thermoelectric elements in the thermoelectric power generation unit are densely arranged in the part directly above the steel material, i.e. the high temperature portion with high output, and the thermoelectric power generation modules or thermoelectric elements in the thermoelectric power generation unit in the width direction are sparsely arranged in the end portion of the steel material, i.e. the low temperature portion with low output. The thermoelectric power generation device with effectively improved power generation efficiency of each individual thermoelectric power generation unit can thus be realized. For example, in the case where the temperature of the steel material is 900° C. and the distance between the thermoelectric power generation unit and the steel material is 153 mm, efficient thermoelectric power generation is achieved by installing the thermoelectric power generation module at intervals of 70 mm in the center portion and at intervals of 78 mm in the end portion in FIG. 11. Moreover, the optimal interval of thermoelectric power generation modules may be studied and set using the thermoelectric power generation module interval in the thermoelectric power generation unit illustrated in FIG. 9 as a parameter.

In this embodiment, the arrangement of thermoelectric power generation modules or thermoelectric elements in each thermoelectric power generation unit may be varied in density as mentioned above, or the arrangement of thermoelectric power generation units may be varied in density.

The embodiment in which the arrangement density of thermoelectric power generation modules or thermoelectric elements is changed is particularly suitable in the case where there is no installation tolerance of the facility in the direction above the steel material. The transporter for controlling the distance between the thermoelectric power generation unit and the steel material may be added to this embodiment, too. Hence, the thermoelectric power generation device can generate power more efficiently while appropriately controlling the distance between the thermoelectric power generation unit and the steel material even in the case of, for example, the temperature variations of the heat source in actual operation.

The expression “depending on the output of the thermoelectric power generation unit” indicates to change the position or the arrangement density of thermoelectric power generation modules or thermoelectric elements according to the temperature of the steel material. In addition, the expression also includes the following measure: in the case where there is an output difference between thermoelectric power generation units when, for example, the thermoelectric power generation units are installed at an initial position, a thermoelectric power generation unit with low output is moved to such a position that increases the output, i.e. installed nearer the steel material. The expression “depending on the temperature” does not only simply mean “based on the temperature of the steel material” but also means “based on the temperature distribution and/or configuration factor of the steel material”.

An example of control based on the output of thermoelectric power generation when a pipe or tube material is used as the heat source is described below.

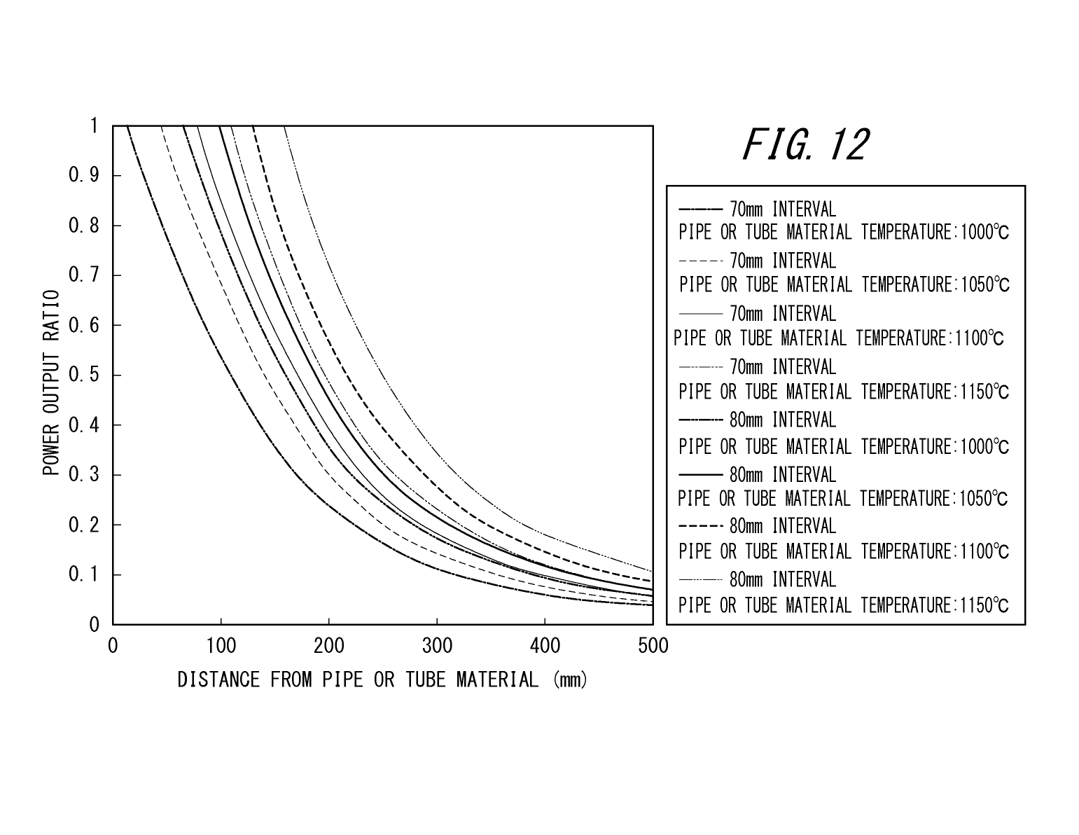

FIG. 12 illustrates the result of studying the relationship between the distance from the pipe or tube material to the thermoelectric power generation unit and the power output ratio using the thermoelectric power generation module interval in the thermoelectric power generation unit and the temperature of the pipe or tube material as parameters. For example, the most efficient thermoelectric power generation is achieved by the following control: when the thermoelectric power generation module interval is 80 mm, the distance between the thermoelectric power generation unit and the pipe or tube material, etc. is set to 150 mm in the case where the temperature of the pipe or tube material is 1150° C., and the distance is changed to 60 mm in the case where the temperature of the pipe or tube material is 1000° C.

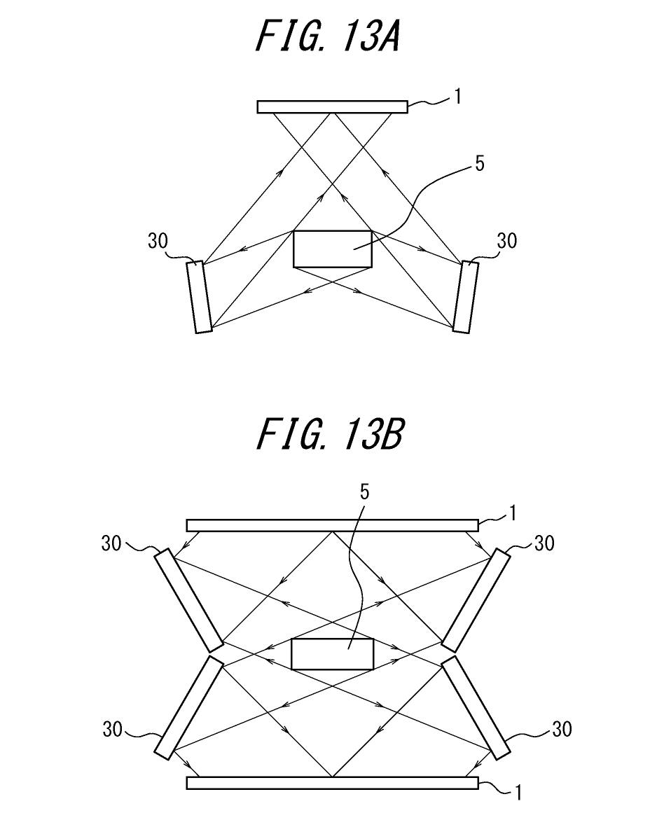

The thermoelectric power generation device may further include a heat reflector for collecting heat, as illustrated in FIGS. 13(a) and (b). In the drawing, reference sign 30 is a heat reflector, and 1 is a thermoelectric power generation unit. The use of such a heat reflector 30 enhances the heat collection efficiency for each individual thermoelectric power generation unit 1, and enables more efficient thermoelectric power generation.

The heat reflector is preferably installed on both sides of the steel material 5 as illustrated in FIG. 13(a) (in the drawing, the travel direction of the steel material is from back to front of the drawing), for heat collection efficiency.

Moreover, four reflectors and two thermoelectric power generation units may be used in combination, as illustrated in FIG. 13(b). While the heat reflector 30 is installed on both sides of the steel material 5 in FIGS. 13(a) and (b), the heat reflector may be installed above and below the steel material depending on the installation position of the thermoelectric power generation unit.

The cross-section of the heat reflector may be flat, curved, V-shaped, or U-shaped. The heat reflector favorably has a surface that ranges from flat to concave. Here, since the aberration at the focal point changes depending on the angle of incidence on the concave heat reflector, it is preferable to install one heat reflector or a group of a plurality of heat reflector surfaces so as to assume an optimal heat reflector shape (curvature) that minimizes the aberration for a predetermined angle of incidence.

The heat reflector may also serve as a heat insulation board. Alternatively, a heat insulation board may be installed outside the heat reflector so as to cover the heat reflector.

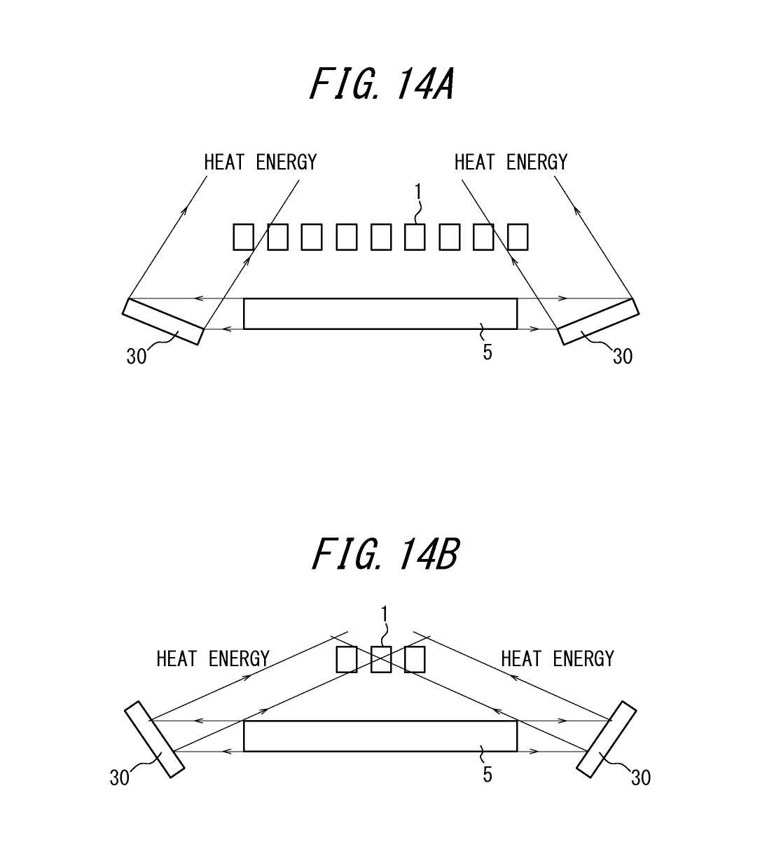

Though the above-mentioned FIG. 13 and the below-mentioned FIG. 14 do not illustrate a separately installed heat insulation board, the heat insulation board may cover the entire reflector or have an opening at the installation position of the thermoelectric power generation unit and the reflector.

In the embodiment in which the heat reflector is used, heat can be collected at any part of the thermoelectric power generation units. This has the advantage of further improving the installation tolerance of the thermoelectric power generation device, as explained below.

For example, by collecting heat at the thermoelectric power generation units 1 with favorable balance as illustrated in FIG. 14(a), the power generation efficiency of the individual thermoelectric power generation units can be further improved even when the thermoelectric power generation units are installed flat as usual in the thermoelectric power generation device. Furthermore, heat energy collected at any part can be applied to the thermoelectric power generation units 1, as illustrated in FIG. 14(b). The advantage of this embodiment lies in that, even in the case where the installation area of the thermoelectric power generation units is limited or in the case where thermoelectric power generation units having a desired area are not available, efficient thermoelectric power generation can be performed by moving the thermoelectric power generation units and also moving the heat reflector 30 appropriately. A drive unit may be provided for the heat reflector 30 so that the heat collection part can be changed by changing the angle according to an external signal.

Thus, the thermoelectric power generation unit installed depending on at least one of the temperature of the steel material and the temperature and output of the thermoelectric power generation unit includes not only the thermoelectric power generation unit for which the distance is set but also the thermoelectric power generation unit for which the distance or the angle can be changed by the heat reflector.

The heat reflector is not particularly limited as long as it can reflect heat energy (infrared radiation). A mirrored metal such as iron, a tinned heat-resistant tile, or the like may be selected as appropriate in consideration of the installation position, the ease of material procurement, etc.

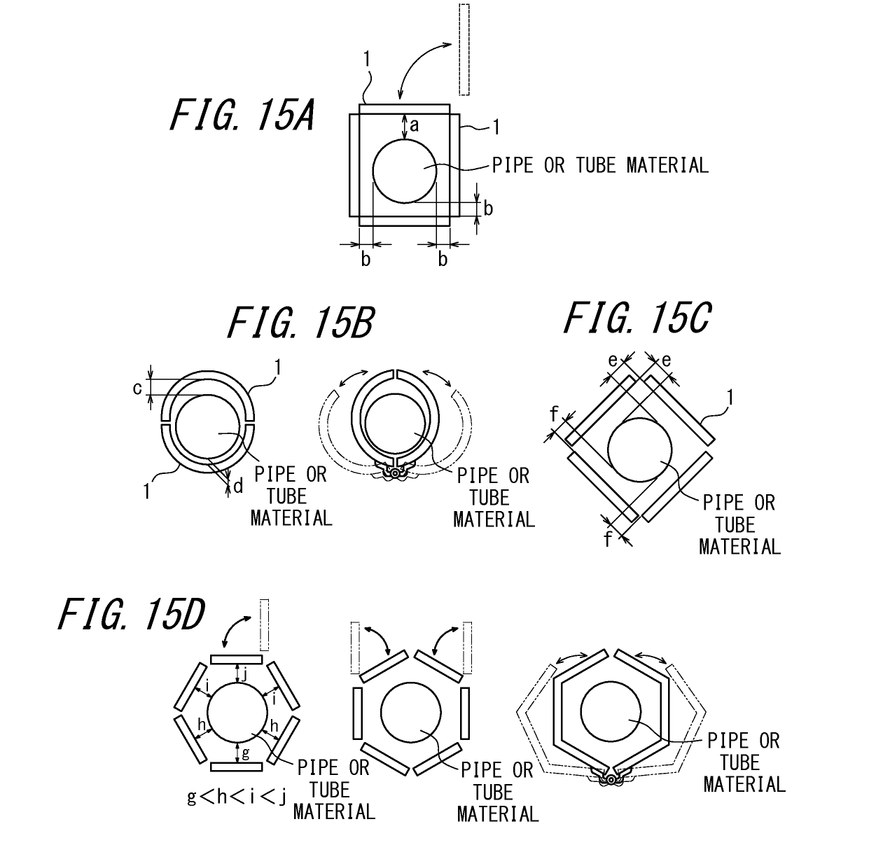

FIG. 15(A) to (D) illustrate examples of installation of thermoelectric power generation units.

The thermoelectric power generation units may be shaped to surround the outer periphery of the steel material, as illustrated in FIG. 15(A) to (D). In particular, this embodiment is preferably applied to such a location where a steel material, e.g. a pipe or tube material, a steel bar, or a wire rod manufactured in a line, is continuously conveyed incessantly and there are many sections in which no roller table for supporting the steel, mill, and the like are present and where a space exists below or on the side of the steel material.

In the case of installing the thermoelectric power generation unit on the side of or below the steel material, the installation is preferably performed so as to satisfy the relationship ds≦du in consideration of the influence of heat convection from the steel material, where ds is the distance between the thermoelectric power generation device and the side or lower surface of the steel material and du is the distance between the thermoelectric power generation device and the upper surface of the steel material.

In FIG. 15(A) to (C), when the distances a, c, and e correspond to the above-mentioned distance du, then the distances b, d, and f correspond to the above-mentioned distance ds, respectively. Note that the distances having the same reference sign such as b, e, and f in the drawing may be different from each other, as long as these distances satisfy the relationship between du and ds.

FIG. 15(D) illustrates an example of adjusting the distance in four levels of g, h, i, and j. These distances preferably satisfy the relationship g<h<i<j. Therefore, in the case where the thermoelectric power generation units surround the outer periphery of the heat source, it is preferable to make the thermoelectric power generation unit nearest the heat source on the lower surface side and gradually increase the distance toward the upper surface side. Note that the distances having the same reference sign such as h and i in FIG. 15(D) may be different from each other.

Thus, in the case where the thermoelectric power generation units surround the outer periphery of the steel material, the distance between the steel material (heat source) and each thermoelectric power generation unit may be varied as appropriate within the same device.

In the case where the thermoelectric power generation units are not installed for all surfaces, a board (heat insulation board) may be installed to prevent the heat of the heat source from escaping outside, thus enabling efficient thermoelectric power generation. The material of the heat insulation board is not particularly limited as long as it is typically used as a heat insulation board of a high temperature object and can resist the temperature of the installation position, e.g. a metal (alloy) such as iron or Inconel, ceramics, etc. The board preferably has low emissivity to reduce the amount of radiant heat, which is generated from the heat source, absorbed by the board so that the heat is transmitted toward the thermoelectric power generation unit.

The thermoelectric power generation device may be provided with at least one opening using the transporter, as illustrated in FIG. 15(A).

The opening is normally covered by the thermoelectric power generation unit. When the operation starts, the thermoelectric power generation unit is moved from the opening, so that the steel material can be safely conveyed without damaging the thermoelectric power generation device. In this embodiment, the heat source may be surrounded by a plurality of thermoelectric power generation devices.

Through the use of the above-mentioned transporter, the thermoelectric power generation unit can be moved from the power generation region to the retraction position to prevent the device from breakage caused by, for example, the variation in height of the steel material in a non-steady state in which the front end, back end, or the like of the steel material serves as the heat source, and then moved back to the power generation region.

For example, in the early stage of the passage of the steel material, the thermoelectric power generation device is positioned in a state of being raised to 1000 mm or more from the pass line so that the steel material does not collide with the thermoelectric power generation device, as illustrated in FIG. 1. After this, when the height variation of the steel material decreases, the thermoelectric power generation device is brought near the steel material by the moving device, as illustrated in FIG. 3. In the case where the steel material is relatively thick or passes successively and the height of the steel material varies little, the thermoelectric power generation device is placed near the steel material as illustrated in FIG. 3. The steel material and the thermoelectric power generation device are preferably apart from each other by 10 mm or more, to prevent the thermoelectric power generation device from coming into contact with the steel material and being broken or damaging the steel material.

A larger moving distance, however, leads to an increase in facility cost. Accordingly, in the case of moving the thermoelectric power generation device up and down, it is sufficient to make the thermoelectric power generation device movable up to about 3000 mm far. A preferable moving distance is 10 mm to 1000 mm.

A distance sensor may be attached on the upstream side and/or downstream side of the thermoelectric power generation device, to set the position of the thermoelectric power generation device by feedforward and/or feedback control using the value of the distance sensor.

The embodiments described above may be freely combined. For example, when the thermoelectric power generation units are installed in the form of an elliptic arc with an extremely large curvature in the case of attempting to achieve optimal thermoelectric power generation efficiency only by distance adjustment, the embodiment of using the heat reflector may be combined to alleviate the curvature.

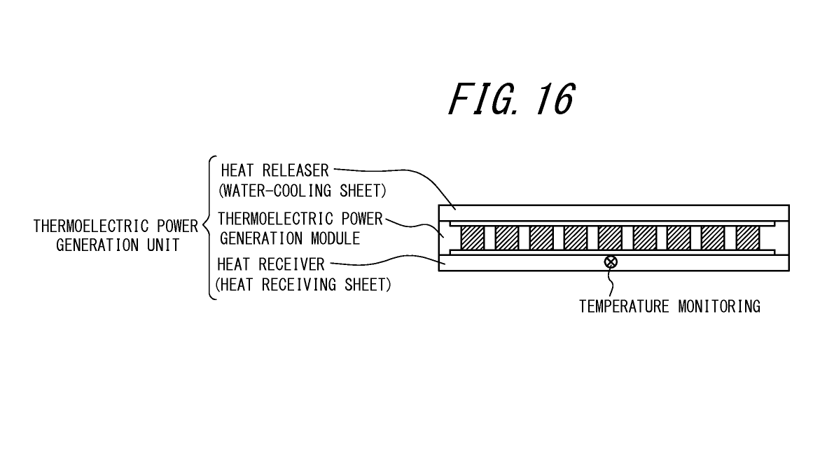

The thermoelectric power generation device may include, in the thermoelectric power generation unit, a temperature monitoring mechanism for monitoring the temperature, as illustrated in FIG. 16. The temperature monitoring mechanism monitors whether or not the temperature of the thermoelectric power generation unit receiving heat from the steel material or the pipe or tube material is within a tolerable temperature range (e.g. the heat resistance temperature of the thermoelectric power generation modules, which is, in the case of BiTe-based modules used here, up to 280° C. and particularly in the range of 250° C. to 280° C. enabling efficient power generation), using a temperature sensor such as a thermocouple. The thermoelectric power generation device may include a position adjusting mechanism for, in the case where an upper limit of the tolerable temperature of the thermoelectric power generation unit is reached as a result of the monitoring, manually or automatically adjusting the distance between the steel material and the thermoelectric power generation unit to keep the temperature at the upper limit of the tolerable temperature range or less.

Preferably, the position adjusting mechanism automatically adjusts the position in the case where the temperature of the thermoelectric power generation unit exceeds the tolerable temperature according to the information from the temperature sensor, to prevent the thermoelectric power generation device from exceeding the heat resistance temperature and being broken. The thermoelectric power generation unit is preferably moved, for example, as illustrated in FIG. 4 or 5.

The position adjusting mechanism includes a mechanism for monitoring, with the temperature sensor such as a thermocouple which is the temperature monitoring mechanism attached to the thermoelectric power generation unit, whether or not the temperature of the thermoelectric power generation unit receiving heat from the steel material or the pipe or tube material is within the temperature range enabling efficient power generation, e.g. 250° C. to 280° C., and manually or automatically adjusting the distance between the steel material and the thermoelectric power generation unit in the case where the temperature is not within the temperature range. The position adjusting mechanism may also serve as the transporter.

The thermoelectric power generation device may also include any of the other embodiments as appropriate, in addition to the temperature monitoring mechanism and the position adjusting mechanism.

The disclosed thermoelectric power generation method converts heat energy radiated from a steel material into electric energy. Accordingly, for example in the manufacturing line illustrated in any of FIGS. 6 to 8, the thermoelectric power generation device illustrated in any of FIGS. 1, 3 to 5, 10 to 11, and 13 to 16, i.e. the thermoelectric power generation device having the transporter capable of moving the thermoelectric power generation unit, is used as a basic structure, which may be combined with any of the following structures: the thermoelectric power generation unit is installed depending on at least one of the temperature of the steel material and the temperature and output of the thermoelectric power generation unit; the thermoelectric power generation unit is installed nearer the steel material in the low temperature portion with low output than in the high temperature portion with high output depending on at least one of the temperature of the steel material and the temperature and output of the thermoelectric power generation unit; the thermoelectric power generation modules or thermoelectric elements in the thermoelectric power generation unit are arranged more densely in the high temperature portion with high output than in the low temperature portion with low output depending on at least one of the temperature of the steel material and the temperature and output of the thermoelectric power generation unit; the heat reflector is provided; the thermoelectric power generation unit surrounds the outer periphery of the steel material; and at least one opening is provided.

Here, the thermoelectric power generation device may be used to receive heat from the steel material to generate power, and move the thermoelectric power generation unit of the thermoelectric power generation device using the generated electric energy. Moreover, when implementing the thermoelectric power generation method, the thermoelectric power generation devices according to the plurality of embodiments described above may be used in combination as appropriate.

### EXAMPLES

To confirm the advantageous effects of the disclosed thermoelectric power generation device, the following test was conducted. In a thermoelectric power generation device that includes thermoelectric power generation units with 50 mm square thermoelectric power generation modules arranged at intervals of 70 mm and that has an area of 1 m², the thermoelectric power generation units were installed at the position C in FIG. 7, and the output of each thermoelectric power generation unit was examined.

In Example 1, the following test was conducted. Upon start of the passage of a rough bar, the distance between the thermoelectric power generation device and the rough bar was set to 3000 mm. After the front end of the rough bar passed, the distance to the rough bar was changed to 775 mm by moving the thermoelectric power generation device. The rough bar used as the steel material here was approximately 1100° C. in temperature in the width center portion, 1050° C. in temperature in the width end portion (the range of approximately 80 mm or less from the width end), 900 mm in width, and 40 mm in thickness.

As a result, the output was 75% of the rated output. The output in the width end portion was 60% of the rated output.

In Example 2, the following test was conducted. Upon start of the passage of a rough bar, the distance between the thermoelectric power generation device and the rough bar was set to 3000 mm. After the front end of the rough bar passed, the distance to the rough bar was changed to 670 mm by moving the thermoelectric power generation device. The rough bar used as the steel material here was approximately 1100° C. in temperature across the full width, 900 mm in width, and 40 mm in thickness.

As a result, power substantially equal to the rated output was obtained in the width direction, while the output in the width end portion was 80% of the rated output.

In Example 3, the following test was conducted. In the structure illustrated in FIG. 10, the distance between the thermoelectric power generation unit and the slab was set to 670 mm in the center portion, and 580 mm in the width end portion. The rough bar having the same temperature distribution as that in Example 2 was used here.

As a result, the output was substantially the rated output across the full width.

In Example 4, the following test was conducted. In the structure illustrated in FIG. 11, the thermoelectric power generation modules in the thermoelectric power generation unit were arranged at intervals of 70 mm in the center portion and at intervals of 79 mm in the width end portion, and the distance between the thermoelectric power generation unit and the slab was set to 670 mm. The rough bar having the same temperature distribution as that in Example 2 was used here.

As a result, the output was substantially the rated output in the width direction. Since the number of thermoelectric power generation modules was small in the width end portion as compared with Example 3, however, the total output was lower than that in Example 3.

In Example 5, the following test was conducted. The thermoelectric power generation modules in the thermoelectric power generation unit were arranged at intervals of 63 mm in the center portion and at intervals of 70 mm in the width end portion, and the distance between the thermoelectric power generation unit and the slab was set to 580 mm. The rough bar having the same temperature distribution as that in Example 2 was used here.

As a result, the output was substantially the rated output in the width direction. Since the number of thermoelectric power generation modules was large as compared with Example 3, the total output was higher than that in Example 3.

In Example 6, the following test was conducted. In the structure illustrated in FIG. 13(a), the heat reflector for collecting heat at the thermoelectric power generation unit was placed. The rough bar having the same temperature distribution as that in Example 2 was used here.

As a result, substantially the rated output was obtained by the thermoelectric power generation unit.

In Example 7, the following test was conducted. Four thermoelectric power generation devices were installed to surround the outer periphery of the rough bar. The rough bar having the same temperature distribution as that in Example 2 was used here.

As a result, the output was 2.1 times that in Example 4 because of the increase in the number of thermoelectric power generation units.

In Example 8, only the thermoelectric power generation unit above the upper surface of the rough bar was movable to provide an opening.

In detail, the following test was conducted. Upon start of the passage of the rough bar, there was an opening above the upper surface of the rough bar. After the stabilization of the passage, the thermoelectric power generation device above the upper surface of the rough bar was brought near the rough bar. The rough bar having the same size and temperature distribution as that in Example 2 was used here.

As a result, the output was substantially the rated output in all thermoelectric power generation devices, without causing breakage of any of the devices.

In Example 9, the distance was adjusted by the transporter so that the temperature of the heat receiving sheet was in the range of 250° C. to 280° C., using the temperature monitoring mechanism attached to the thermoelectric power generation unit. The rough bar having the same temperature distribution as that in Example 2 was used here. As a result, the output was substantially the rated output across the full width.

In Example 10, the following test was conducted. The temperature monitoring mechanism was attached to the thermoelectric power generation unit. When the temperature of the heat receiving sheet exceeded 280° C., the transporter automatically acted to retract the thermoelectric power generation unit away from the heat source. As a result, the thermoelectric power generation modules were able to be operated within the heat resistance temperature, to maintain performance.

In Comparative Example 1, the following test was conducted. The same thermoelectric power generation units and rough bar as those in Example 1 were used, where the thermoelectric power generation units were installed at the same position as in Example 1. Upon the installation, the distance between the thermoelectric power generation device and the rough bar was set to 3000 mm so as not to break the thermoelectric power generation device. As a result, the output was only about 1% of the rated output.

In Comparative Example 2, in a thermoelectric power generation device including thermoelectric power generation units with thermoelectric power generation modules whose thermoelectric power generation performance degraded due to long use, the output was subjected to monitoring but the temperature was not subjected to monitoring, so that part of the thermoelectric power generation modules exceeded the tolerable temperature and the thermoelectric power generation device was partly broken.

The results of Examples and Comparative Examples described above demonstrate the advantageous effects of the disclosed thermoelectric power generation device. Though the installation position of the thermoelectric power generation unit was changed to avoid a non-steady state or depending on the temperature of the rough bar as the steel material in the foregoing Examples, the same results were confirmed even by moving the thermoelectric power generation device depending on the temperature of a hot slab in a continuous caster, a slab or a hot-rolled steel strip in a hot rolling device, a sheet material or a pipe or tube material in a forge welded pipe or tube facility, or any other bar steel such as a steel pipe or tube, a steel bar, a wire rod, and a rail, by moving the thermoelectric power generation device depending on the output of the thermoelectric power generation unit, or by moving the thermoelectric power generation device that surrounds the outer periphery or the thermoelectric power generation device having an opening.

### INDUSTRIAL APPLICABILITY

Heat generated from a steel material can be effectively converted into electric power, which contributes to energy saving in manufacturing plants.

### REFERENCE SIGNS LIST

1 thermoelectric power generation unit

2 transporter

3 thermoelectric power generation device

4 table roller

5 steel material

6 thermoelectric element

7 electrode

8 thermoelectric power generation module

9 insulator

10 heat receiver

11 heat releaser

12 ladle

13 tundish

14 mold

15 slab cooling device

16 roller group such as straightening rolls

17 slab cutting device

18 thermometer

19 thermoelectric power generation device

20 dummy bar table

21 steel sheet

22 pipe or tube material

23 heating furnace

24 forming machine/forge welder

25 hot reducer

26 rotary hot saw

27 cooling bed

28 sizer

29 straightener

30 heat reflector

1. A thermoelectric power generation device comprising:
a thermoelectric power generation unit that converts heat energy radiated from a steel material into electric energy; and
a transporter capable of moving the thermoelectric power generation unit.

2. The thermoelectric power generation device according to claim 1,
wherein the thermoelectric power generation unit is installed to face the steel material and depending on an output of the thermoelectric power generation unit.

3. The thermoelectric power generation device according to claim 1,
wherein the thermoelectric power generation unit is installed nearer the steel material in a low temperature portion with low output than in a high temperature portion with high output, depending on an output of the thermoelectric power generation unit.

4. The thermoelectric power generation device according to claim 1,
wherein one or more thermoelectric power generation modules or thermoelectric elements in the thermoelectric power generation unit are arranged more densely in a high temperature portion with high output than in a low temperature portion with low output, depending on an output of the thermoelectric power generation unit.

5. The thermoelectric power generation device according to claim 1, comprising a heat reflector.

6. The thermoelectric power generation device according to claim 1,
wherein the thermoelectric power generation unit is installed further depending on at least one of a temperature of the thermoelectric power generation unit and a temperature of the steel material.

7. The thermoelectric power generation device according to claim 1,
wherein the transporter controls a distance between the thermoelectric power generation unit and the steel material, depending on at least one of a temperature and an output obtained by measuring at least one of: a temperature of the steel material; a temperature of the thermoelectric power generation unit; and an output of the thermoelectric power generation unit.

8. The thermoelectric power generation device according to claim 1,
wherein the thermoelectric power generation device is shaped to surround an outer periphery of the steel material.

9. The thermoelectric power generation device according to claim 1,
wherein the thermoelectric power generation device is provided with at least one opening.

10. A thermoelectric power generation method of receiving heat of a steel material and performing thermoelectric power generation, using the thermoelectric power generation device according to claim 1.

11. The thermoelectric power generation device according to claim 1,
wherein the thermoelectric power generation unit includes a mechanism for monitoring a temperature of the thermoelectric power generation unit, and
the thermoelectric power generation device comprises a position adjusting mechanism for, when the temperature monitored by the mechanism reaches an upper limit of a tolerable temperature range an upper limit of a tolerable temperature range of the thermoelectric power generation unit, moving the thermoelectric power generation unit to keep the temperature of the thermoelectric power generation unit at or below the upper limit of the tolerable temperature range.

12. The thermoelectric power generation device according to claim 11,
wherein the mechanism for monitoring has a thermocouple that is placed at a position for measuring a temperature of a heat receiving sheet of the thermoelectric power generation unit.

13. The thermoelectric power generation device according to claim 11,
wherein the thermoelectric power generation unit is installed to face the steel material and depending on at least one of a temperature and an output of the thermoelectric power generation unit.

14. A thermoelectric power generation method of receiving heat of a steel material to generate power using the thermoelectric power generation device according to claim 11, and moving the thermoelectric power generation unit of the thermoelectric power generation device using generated electric energy.

15. The thermoelectric power generation device according to claim 2,
wherein the thermoelectric power generation unit is installed nearer the steel material in a low temperature portion with low output than in a high temperature portion with high output, depending on an output of the thermoelectric power generation unit.

16. The thermoelectric power generation device according to claim 2,
wherein one or more thermoelectric power generation modules or thermoelectric elements in the thermoelectric power generation unit are arranged more densely in a high temperature portion with high output than in a low temperature portion with low output, depending on an output of the thermoelectric power generation unit.

17. The thermoelectric power generation device according to claim 3,
wherein one or more thermoelectric power generation modules or thermoelectric elements in the thermoelectric power generation unit are arranged more densely in a high temperature portion with high output than in a low temperature portion with low output, depending on an output of the thermoelectric power generation unit.

18. The thermoelectric power generation device according to claim 15,
wherein one or more thermoelectric power generation modules or thermoelectric elements in the thermoelectric power generation unit are arranged more densely in a high temperature portion with high output than in a low temperature portion with low output, depending on an output of the thermoelectric power generation unit.

19. A thermoelectric power generation method of receiving heat of a steel material to generate power using the thermoelectric power generation device according to claim 12, and moving the thermoelectric power generation unit of the thermoelectric power generation device using generated electric energy.

20. A thermoelectric power generation method of receiving heat of a steel material to generate power using the thermoelectric power generation device according to claim 13, and moving the thermoelectric power generation unit of the thermoelectric power generation device using generated electric energy.
